(19) United States
(12) Patent Application Publication
(10) Pub. No.: US 2002/0062789 A1
(43) Pub. Date: May 30, 2002

(54) Apparatus and method for multi-layer deposition

(76) Inventors: Tue Nguyen, Fremont, CA (US); Craig Alan Bercaw, Los Gatos, CA (US)

Correspondence Address: Tue Nguyen, 496 Olive Ave., Fremont, CA, 94539, US

(21) Appl. No.: 09/725,658

(22) Filed: Nov. 29, 2000

(51) Int. Cl. C23C 16/00

(52) U.S. Cl. 118/715; 427/255.28

(57) ABSTRACT

An apparatus controls deposition rate of multi-layer films deposited by chemical vapor deposition (CVD). The apparatus includes a CVD chamber; a vapor precursor injector coupled to the CVD chamber; and a liquid precursor injector coupled to the CVD chamber.

### FIELD OF THE INVENTION

The present invention relates to the apparatus and methods for the deposition of multi-layer films in semiconductor device processing.

### BACKGROUND

Aluminum has been used as an interconnecting metal for semiconductor device fabrication for many years. Aluminum has high electrical conductivity, approximately 3 μΩ-cm, and is easily deposited onto substrates using evaporation or sputtering. Aluminum bonds well to virtually all materials used in semiconductor device fabrication such as silicon, silicon dioxide, silicon nitride, titanium nitride, among others. Copper metallization using electrochemical plating (ECD) or chemical vapor deposition (CVD) is now replacing aluminum as the interconnection metallization of choice in the fabrication of integrated circuits due to its lower resistivity (approximately 2 μΩ-cm).

Typical CVD copper processes use liquid precursors for the deposition of copper thin films on an IC substrate. Typically, a copper liquid precursor is first turned into vapor, and the vapor then reacts on the substrate. One type of liquid-precursor vapor delivery system draws the vapor from the liquid precursor. This technique works well with highly volatile liquid with high vapor pressure. The liquid precursor can also be heated up to further increase the vapor pressure. A delivery line then needs to be heated up to prevent re-condensation. Another technique to increase the amount of vapor precursor of a liquid precursor is bubbling. A carrier gas is bubbled through the liquid precursor. The carrier gas then carries the vapor precursor to the processing chamber. A basic characteristic of this system is a slow precursor flow rate.

To have high deposition rate with low vapor pressure precursors, a liquid precursor injection system is required. The basic difference between a liquid precursor vapor delivery system and a liquid precursor injection system is the method of carrying the precursor. Liquid precursor vapor delivery system carries the precursor vapor directly to the process chamber while liquid precursor injection system carries the precursor liquid to the process chamber through a vaporizer. Basic components of a liquid precursor injection system include a liquid delivery line and a vaporizer. The liquid delivery line carries the liquid precursor from the liquid container to the vaporizer. The liquid delivery line often contains a liquid metering device such as a liquid flow controller or a liquid pump to control the liquid flow rate. The vaporizer converts the liquid precursor into vapor form before delivering on the wafer substrate. A carrier gas is normally used in the vaporizer to carry the precursor vapor to the substrate.

One difficulty with copper deposition process is the poor adhesion of ECD or CVD copper. Unlike sputtered copper process, which depends on kinetic energy for copper to form a bond with the under-layer, ECD or CVD copper has little or no kinetic energy, thus depends on chemical reaction. Furthermore, copper metallization process requires a diffusion barrier under-layer such as TiN, TaN, TiON, WN, etc. to prevent copper migration, leading to device degradation. To be an effective copper diffusion barrier, the material needs to have minimal chemical reaction with copper to enhance the poor adhesion characteristics of ECD or CVD copper.

To improve the adhesion of ECD or CVD copper, a conventional method deposits a thin layer of sputtered copper to serve as an adhesion layer. The drawback of this technique is the limitation in the conformality of the sputter process, leading to void or pin holes. Also, additional equipment (a sputter tool) would be required, raising the process cost.

FIG. 1 shows another prior art liquid precursor vapor delivery system. A liquid precursor 23 is stored in a container 22 and has a vapor precursor 26 co-existing in the container. A heater 24 is used to heat the container 22 to increase the precursor vapor pressure. A carrier gas 29 is used to bubble through the liquid precursor to increase the precursor vapor carried through a precursor delivery line 21. The precursor delivery line 21 is used to take the precursor vapor out of the container to a processing chamber 5. A second heater 25 is used to heat the delivery line to prevent condensation. A vapor metering device 20 is used to control the amount of vapor flow from the precursor container to the processing chamber 5. Optionally a vapor metering device could be connected to the carrier gas 29 to control the amount of carrier flow. The flow 27 carries precursor vapor from the vapor 26 to the vapor metering device 20 before reaching the processing chamber 5.

FIG. 2 shows another prior art liquid precursor injection system. This system injects the liquid precursor 33 through a delivery line 31, and then converts the liquid to vapor form in a vaporizer 38. The liquid precursor 33 is stored in a container 32. A push gas 39 is used to push the liquid precursor to the delivery line 31. A heater 36 is used to heat the vaporizer 38 to convert the liquid precursor to vapor form. A flow line 37 carries precursor liquid from the liquid container 32 to a liquid metering device 30 such as a liquid flow controller (LFC) or a liquid pump before reaching the processing chamber 5 via the vaporizer 38.

Additionally, Nguyen et al., in U.S. Pat. No. 5,948,467, entitled “Enhanced CVD copper adhesion by two-step deposition process”, disclosed a method to improve the adhesion of copper by a two-step deposition process, a first step of low liquid flow rate and a second step of high liquid flow rate. Nguyen et al. suggested that the initially low liquid flow rate would reduce the amount of organic solvent present in the precursor liquid, which is responsible for the inhibition of the chemical reaction necessary for adhesion.

### SUMMARY

In one aspect, an apparatus controls deposition rate of multi-layer films deposited by chemical vapor deposition (CVD). The apparatus includes a CVD chamber; a vapor precursor injector coupled to the CVD chamber; and a liquid precursor injector coupled to the CVD chamber.

Implementations of the above aspect may include one or more of the following. The vapor precursor injector can pass a carrier gas through a liquid precursor. The carrier gas can be a mixture of a plurality of gases. A gas mass flow controller can be connect to the vapor precursor injector to control the flow of the carrier gas. A temperature controller can be connected to the vapor precursor injector to control the temperature of the liquid precursor. The vapor precursor injector can include a bypass passage coupled to the vapor precursor injector; and a bypass valve manifold coupled to the bypass passage and the chamber to allow the carrier gas and a precursor vapor to be switched from the bypass passage to a CVD chamber and back to the bypass passage. The vapor precursor injector can receive additional gases to be injected into the CVD chamber without passing through the liquid precursor. The vapor precursor injector can draw vapor from a liquid precursor. The liquid precursor injector can include a liquid metering device to control the flow of the liquid precursor; and a vaporizer coupled to the liquid metering device to receive the liquid precursor and convert the liquid precursor into vapor. A vaporizer temperature controller can be connected to the vaporizer. An atomizer can also be connected to the vaporizer. The vaporizer can receive a plurality of gases.

In a second aspect, a method for controlling a range of deposition rate of multi-layer films deposited by CVD using liquid precursors having a vapor precursor injector and a liquid precursor injector by depositing a first layer using the vapor precursor injector at a first deposition rate; and depositing a second layer using the liquid precursor injector at a second deposition rate, wherein the second deposition rate is greater than the first deposition rate.

Implementations of the second aspect may include one or more of the following. The second layer can be deposited after the first layer, or the first layer can be deposited after the second layer. A multi-layer film can be formed with a plurality of alternating first and second layers. The liquid precursor can be a liquid copper precursor, and can be also one of liquid aluminum precursor, liquid ferroelectric precursor, liquid high-dielectric-constant precursor. The thickness of the first layer can be approximately between 10 and 500 angstroms. The liquid precursor vapor flow of the precursor vapor injector is approximately between 10 and 1000 standard cubic centimeter per minute (sccm). The deposition rate of the precursor vapor injector can be approximately between 10 and 500 angstroms per minute. The thickness of the second layer can be approximately between 200 and 10000 angstroms. The liquid precursor flow of the liquid precursor injector can be approximately between 0.1 and 5 milliliter per minute. The deposition rate of the liquid precursor injector can be approximately between 500 and 10000 angstroms per minute. An oxidizer can be used during the deposition of the first layer. The oxidizer can be one of oxygen, water vapor, nitrous oxide, oxygen-released chemical.

In yet another aspect, an apparatus controls deposition rate of multi-layer films deposited by chemical vapor deposition (CVD). The apparatus includes a CVD chamber; a vapor precursor injector coupled to the CVD chamber to provide a slow deposition rate; and a liquid precursor injector coupled to the CVD chamber to provide a fast deposition rate.

Advantages of the invention may include one or more of the following. The dual liquid delivery systems enables the low flow rate and the high flow rate steps operate from separate precursor sources to allow additional adhesion improvements. The liquid precursor vapor delivery system provides an accurate low flow rate with large delivery line to prevent clogging. The liquid precursor injection system provides a fast flow rate for high deposition rate.

The liquid precursor injection system provides a fast flow rate for high deposition rate. The liquid precursor vapor delivery system provides a low flow rate for better gap fill property. The dual liquid delivery systems also support separate precursor sources. The low flow rate system further comprises additional chemistry to change the characteristics of the slow deposited layer, thus could enhance different property such as adhesion. The fast flow rate system could further comprise additional chemistry to improve the characteristics of the fast deposited layer such as lower resistivity.

The system provides improved and repeatable adhesion of materials, and in particular CVD copper, to various barrier layers, and in particular TiN, TaN, WN, etc., by multi-layer deposition with a slow flow and a fast flow rates. A liquid precursor vapor delivery system is used for the initial deposition followed by deposition using a liquid precursor injection system. This apparatus provides a very controllable initial deposition at very low flow rates.

The system allows the deposition of multi-layer films using a slow flow rate and a fast flow rate delivery units. The slow flow rate is provided by a liquid precursor vapor delivery system and the fast flow rate is provided by a liquid precursor injection system. The liquid precursor vapor delivery system further includes additional vapor inlet to allow changes in the chemical reaction during the slow deposition step, resulting in a slow-deposition layer with improved characteristics such as improved adhesion. The liquid precursor injection system also further includes additional vapor inlet to allow changes in the chemical reaction during the fast deposition step, resulting in a fast-deposition layer with improved characteristics such as improved resistivity.

### BRIEF DESCRIPTION OF THE DRAWINGS

FIG. 1 shows a prior art liquid precursor vapor delivery system.

FIG. 2 shows a prior art liquid precursor injection system.

FIG. 3 shows an apparatus for liquid and vapor precursor delivery.

FIG. 4 shows an implementation of the apparatus for liquid and vapor precursor delivery of FIG. 3.

FIG. 5 shows a first exemplary process for depositing copper.

FIG. 6 shows a second exemplary process for depositing copper.

FIG. 7 shows a third exemplary process for depositing copper.

FIG. 8 shows a fourth exemplary process for depositing copper.

FIG. 9 shows a fifth exemplary process for depositing copper.

FIG. 10 shows a sixth exemplary process for depositing copper.

FIG. 11 shows a seventh exemplary process for depositing copper.

FIGS. 12A-12C show an exemplary process for operating the apparatus of FIG. 4.

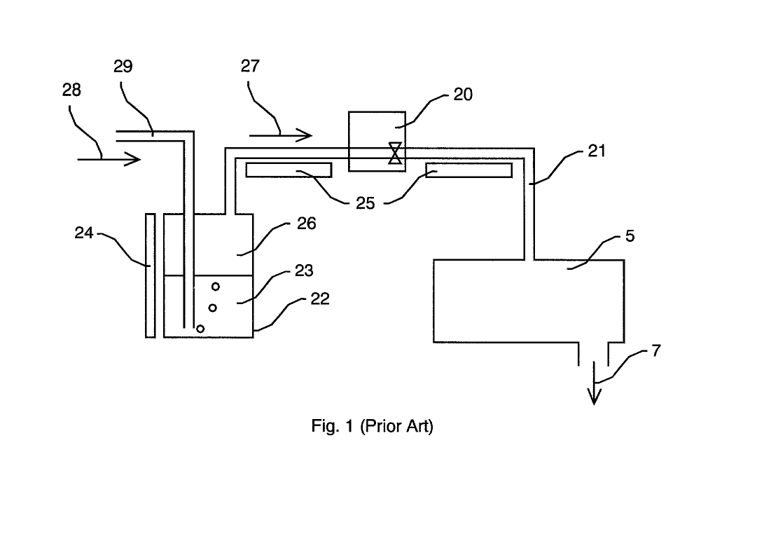

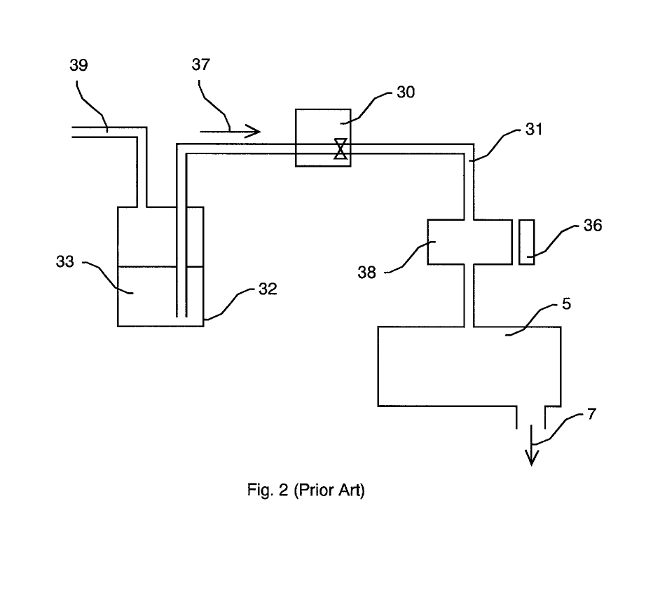

### DETAIL DESCRIPTION

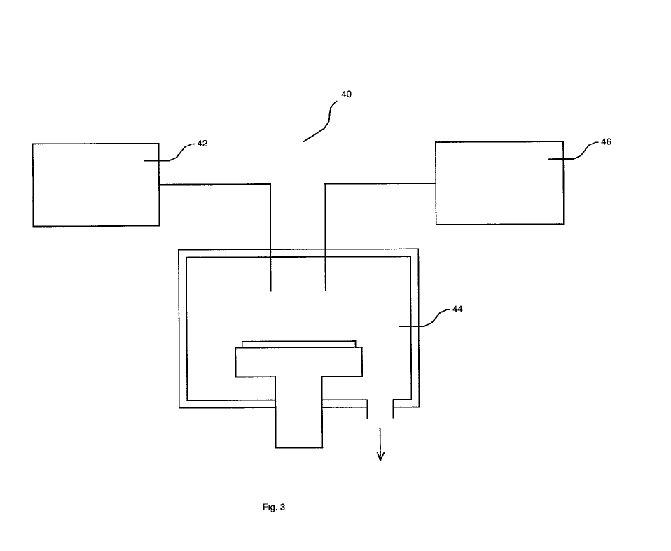

FIG. 3 shows an apparatus 40 for liquid and vapor precursor delivery. The apparatus 40 includes a CVD chamber 44. The CVD chamber 40 includes a chamber body that defines an evacuable enclosure for carrying out substrate processing. The chamber body has a plurality of ports including at least a substrate entry port that is selectively sealed by a slit valve and a side port through which a substrate support member can move. The apparatus 40 also includes a vapor precursor injector 46 connected to the CVD chamber 44 and a liquid precursor injector 42 connected to the CVD chamber 40. In these drawings, some of controlled valves have been omitted for clarity. Such valves are used to control the start, stop and even the flow rate of the precursor.

FIG. 4 shows an embodiment of FIG. 3. In the liquid precursor injector 42, a precursor 60 is placed in a sealed container 61. An inert gas 62, such as argon, is injected into the container 61 through a tube 63 to increase the pressure in the container 61 to cause the copper precursor 60 to flow through a tube 64 when a valve 65 is opened. The liquid precursor 60 is metered by a liquid mass flow controller 66 and flows into a tube 67 and into a vaporizer 68, which is attached to the CVD chamber 71. The vaporizer 68 heats the liquid causing the precursor 60 to vaporize into a gas 69 and flow over a substrate 70, which is heated to an appropriate temperature by a susceptor to cause the copper precursor 60 to decompose and deposit a copper layer on the substrate 70. The CVD chamber 71 is sealed from the atmosphere with exhaust pumping 72 and allows the deposition to occur in a controlled partial vacuum.

In the vapor precursor injector 46, a liquid precursor 88 is contained in a sealed container 89 which is surrounded by a temperature controlled jacket 100 and allows the precursor temperature to be controlled to within 0.1° C. A thermocouple (not shown) is immersed in the precursor 88 and an electronic control circuit (not shown) controls the temperature of the jacket 100, which controls the temperature of the liquid precursor and thereby controls the precursor vapor pressure. The liquid precursor can be either heated or cooled to provide the proper vapor pressure required for a particular deposition process. A carrier gas 80 is allowed to flow through a gas mass flow controller 82 when valve 83 and either valve 92 or valve 95 but not both are opened. Also shown is one or more additional gas mass flow controllers 86 to allow additional gases 84 to also flow when valve 87 is opened, if desired. Additional gases 97 can also be injected into the vaporizer 68 through an inlet tube attached to valve 79, which is attached to a gas mass flow controller 99. Depending on its vapor pressure, a certain amount of precursor 88 will be carried by the carrier gases 80 and 84, and exhausted through tube 93 when valve 92 is open. After the substrate has been placed into the CVD chamber 71 and has reached an appropriate temperature, valve 92 is closed and valve 95 is opened allowing the carrier gases 80 and 84 and the precursor vapor to enter the vaporizer 68 through the attached tube 96 attached tube 96. Such a valve arrangement prevents a burst of vapor into the chamber 71. The precursor 88 is already a vapor and the vaporizer is only used as a showerhead to evenly distribute the precursor vapor over substrate 70. After a predetermined time, depending on the deposition rate of the copper and the thickness required for the initial copper deposition, valve 95 is closed and valve 92 is opened. The flow rate of the carrier gas can be accurately controlled to as little as 1 sccm per minute and the vapor pressure of the precursor can be reduced to a fraction of an atmosphere by cooling the precursor 88. Such an arrangement allows for accurately controlling the copper deposition rate to less than 10 angstroms per minute if so desired. Upon completion of the deposition of the initial copper layer, the liquid source delivery system can be activated and further deposition can proceed at a more rapid rate.

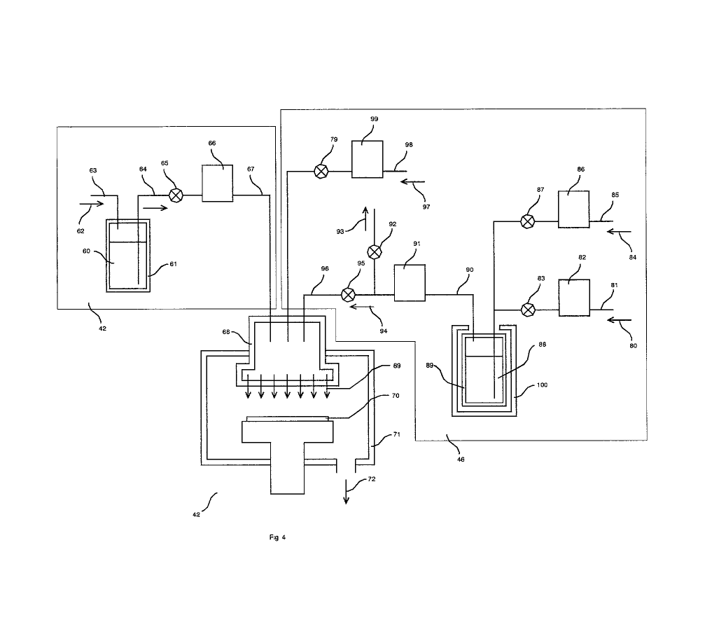

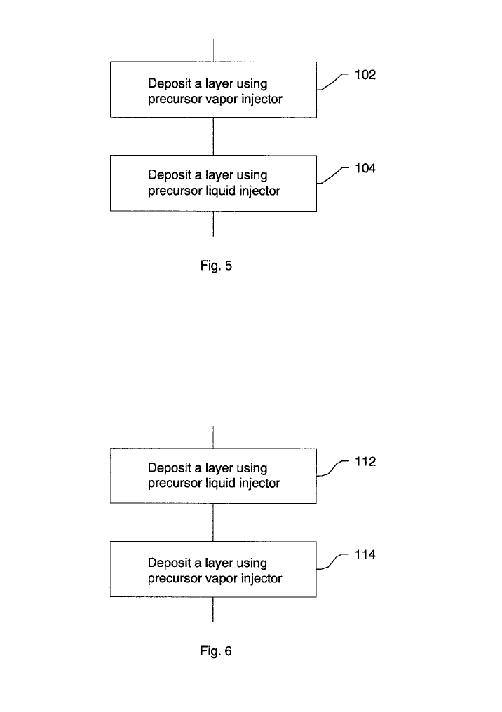

FIG. 5 shows a first exemplary process for depositing copper. In this process, a layer is deposited using the precursor vapor injector 46 (step 102). Next, a layer of material using a precursor liquid injector 42 (step 104).

FIG. 6 shows a second exemplary process for depositing copper. In this process, a layer of material using a precursor liquid injector 42 (step 112). Next, a layer is deposited using the precursor vapor injector 46 (step 114).

FIG. 7 shows a third exemplary process for depositing copper. In this process, a layer is deposited using the precursor vapor injector 46 (step 122). Next, a layer of material using a precursor liquid injector 42 (step 124). Additionally, another layer is deposited using the precursor vapor injector 46 (step 126).

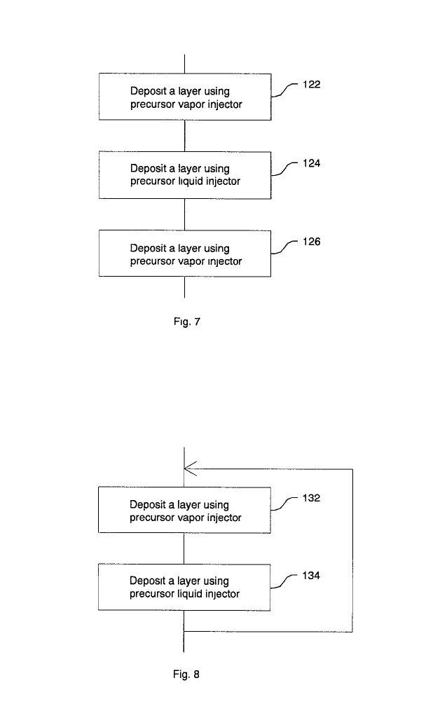

FIG. 8 shows a fourth exemplary process for depositing copper. In this process, a layer is deposited using the precursor vapor injector 46 (step 132). Next, a layer of material using a precursor liquid injector 42 (step 134). Steps 132-134 are iteratively repeated to provide a multilayer film.

FIG. 9 shows a fifth exemplary process for depositing copper. In this process, a layer of material using a precursor liquid injector 42 (step 142). Next, a layer is deposited using the precursor vapor injector 46 (step 144). Steps 142-144 are iteratively repeated to provide a multilayer film.

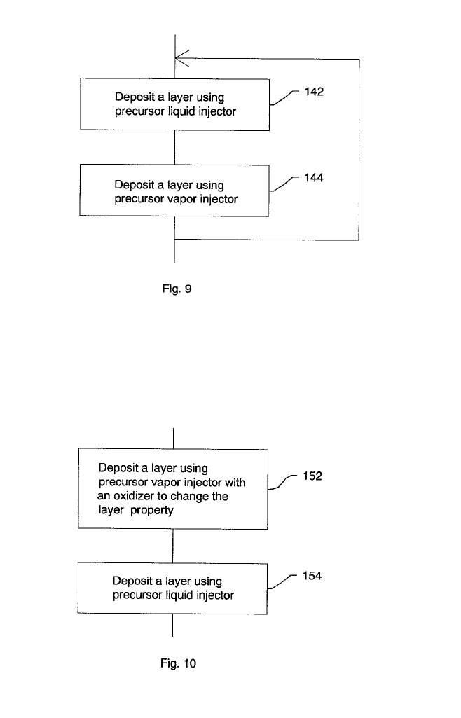

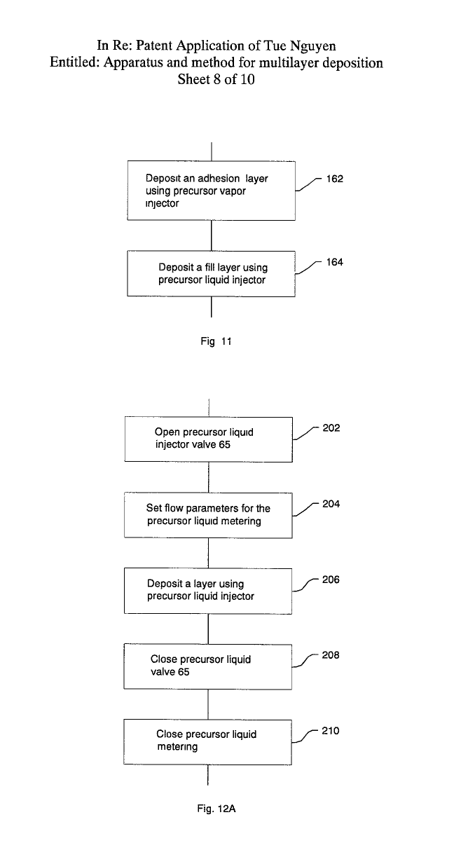

FIG. 10 shows a sixth exemplary process for depositing copper. In this process, a layer is deposited in the presence of an oxidizer using the precursor vapor injector 46 (step 152). Next, a layer of material using a precursor liquid injector 42 (step 154).

FIG. 11 shows a seventh exemplary process for depositing copper. In this process, an adhesive layer is deposited using the precursor vapor injector 46 (step 162). Next, a fill layer of material using a precursor liquid injector 42 (step 164). The adhesion of the deposited copper film to the under-layer is improved because the copper atoms has time to react with the under-layer atoms, then a thick fast layer of copper is subsequently deposited at a fast rate by the liquid precursor injection system to achieve a desired thickness.

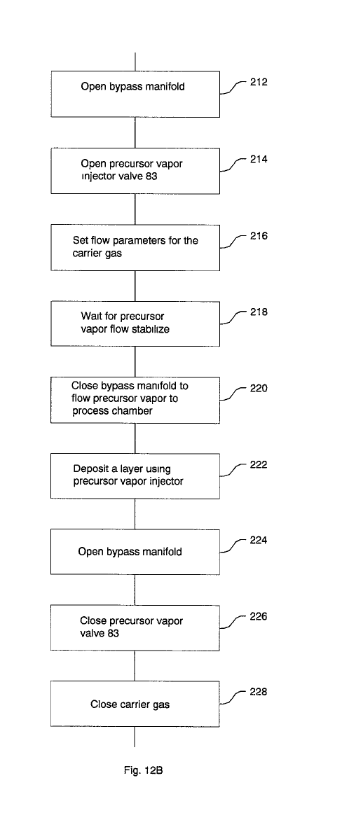

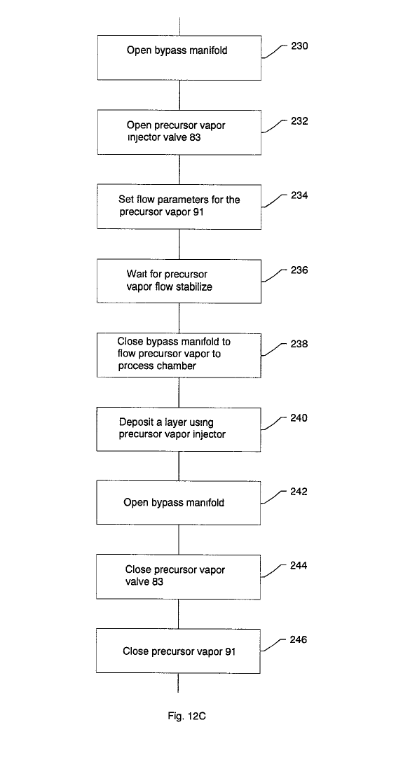

FIGS. 12A-12C show an exemplary process for operating the apparatus of FIG. 4. First, the process opens the valve 65 (step 202). Next, flow parameters are set (step 204). A layer of material is deposited using the liquid injector (step 206). The valve 65 is then closed (step 208). The liquid metering device is also closed (step 210). In this manner, the liquid injector is deployed.

FIGS. 12B-12C shows the operation of the vapor injector. Turning now to FIG. 12B, the process opens a bypass manifold (step 212). This can be done by opening valve 92 and closing valve 95 The valve 83 is then opened (step 214). The carrier gas flow is initiated (step 216), and the process waits for a predetermined duration to stabilize the flow (step 218). The process then closes the bypass manifold to flow to chamber (step 220). Next, the material such as copper is deposited (step 222). The process then opens the manifold (step 224) and closes the valve 83 (step 226). Also, the carrier flow is closed (step 228).

Referring now to FIG. 12C, the process opens the bypass manifold (step 230). The valve 83 is opened (step 232), and the precursor vapor is allowed to flow (step 234). Next, the process waits to stabilize the vapor flow (step 236). The process then closes the bypass manifold (step 238) and allows the material to be deposited (step 240). The process then opens the bypass manifold (step 242) and closes the valve 83 (step 24). The process then closes the precursor vapor flow to the metering device (step 246).

One embodiment includes a liquid precursor vapor delivery system for controlling a slow deposition rate and a liquid precursor injection system for controlling a fast deposition rate. The liquid precursor vapor delivery system provides the liquid precursor vapor into the process chamber. The liquid precursor vapor could simply be drawn from the liquid precursor container, or having a carrier gas passing through the liquid precursor. The carrier gas could have a flow controller to control the amount of carrier gas entering the liquid precursor. The liquid precursor vapor could also have a flow controller to control the amount of precursor vapor flow rate. To stabilizing the precursor vapor flow, a bypass valve manifold could be included to allow precise control of the precursor vapor flow into the process chamber. To control the precursor vapor pressure, a temperature controller could be included to adjust the temperature of the liquid precursor container.

The liquid precursor vapor delivery system further includes various vapors to modify the chemical reaction. Additional vapors could flow through the liquid precursor or directly into the process chamber. For example, the addition of oxygen could change the deposited film property to be more oxygen-rich.

The liquid precursor injection system provides the liquid precursor to the process chamber via a vaporizer, which converts the liquid into vapor form. The liquid precursor injection system also includes a liquid metering device such as a liquid pump or a liquid flow controller (LFC) to control accurately the flow of the liquid precursor. The vaporizer could further include a temperature controller to control the vaporizer temperature. The liquid precursor injection system could also include an atomizer such as an ultrasonic atomizer for converting the liquid precursor into small droplets to improve the efficiency of the vaporizer. The liquid precursor injection system further includes various additional vapors to modify the chemical reaction. Additional vapor could flow through the vaporizer or directly into the process chamber. For example, the addition of a small amount of water vapor improves significantly the film characteristics of CVD copper using copper hexafluoroacetylacetone trimethylvinylsilane (copper-hfac-tmvs) precursor.

The method to deposit a multi-layer film uses a liquid precursor vapor delivery system and a liquid precursor injection system. The method provides a sequential deposition of two layers, a slow deposited layer using the liquid precursor vapor delivery system for controlling a slow deposition rate and a fast deposited layer using the liquid precursor injection system for controlling a fast deposition rate. The liquid precursor could be copper precursors such as copper-hfac-tmvs, aluminum precursors, high-dielectric-constant precursors, or barrier precursors. In the case of copper precursor, an initial slow deposition rate improves the adhesion of the deposited copper. A final slow deposition rate also improves the gap fill property of the deposited copper film. The slow deposition rate is typically defined to be between 10 to 500 angstrom per minute, or when a deposition thickness of 10-500 angstrom is achieved, or when the precursor vapor flow (in gaseous form) is of 10-1000 standard cubic centimeter per minute (sccm). The fast deposition rate is typically defined to be between 500 to 10,000 angstrom per minute, or when a deposition thickness of 200-10000 angstrom is achieved, or when the liquid precursor flow (in liquid form) is of 0.1-5 milliliter per minute (one milliliter is equivalent to one cm3 in liquid form).

Further addition of oxygen such as oxygen gas, water vapor, nitrous oxide, oxygen-released chemical, etc. in copper deposition system causes some of the copper to form copper oxide and thus increasing the adhesion of the copper layer to the under-layer material. Oxidizing the fast copper layer is not desirable because of the high resistivity, but oxidizing the slow copper layer to improve adhesion is acceptable since the slow copper layer is very thin compared to the fast copper layer. Co-patent applications “Multi-layer diffusion barrier structure for improving adhesion property”, application No. 09/520,107 and “Multi-layer copper structure for improving adhesion property”, application No. 09/519,965, of the same inventor, the content of which is hereby incorporated by reference, also disclosed multi-layer method to improve adhesion of copper layer by partially oxidizing a thin lower layer.

Although a preferred embodiment of practicing the method of the invention has been disclosed, it will be appreciated that further modifications and variations thereto may be made while keeping within the scope of the invention as defined in the appended claims.

What is claimed is:

1. An apparatus for controlling deposition rate of multi-layer films deposited by chemical vapor deposition (CVD), the apparatus comprising:
a CVD chamber;
a vapor precursor injector coupled to the CVD chamber; and
a liquid precursor injector coupled to the CVD chamber.

2. The apparatus of claim 1, wherein the vapor precursor injector passes a carrier gas through a liquid precursor.

3. The apparatus of claim 2, wherein the carrier gas is a mixture of a plurality of gases.

4. The apparatus of claim 2, further comprising a gas mass flow controller coupled to the vapor precursor injector to control the flow of the carrier gas.

5. The apparatus of claim 2 further comprising a temperature controller coupled to the vapor precursor injector to control the temperature of the liquid precursor.

6. The apparatus of claim 2, wherein the vapor precursor injector further comprises:
a bypass passage coupled to the vapor precursor injector; and
a bypass valve manifold coupled to the bypass passage and the chamber to allow the carrier gas and a precursor vapor to be switched from the bypass passage to a CVD chamber and back to the bypass passage.

7. The apparatus of claim 1, wherein the vapor precursor injector receives additional gases to be injected into the CVD chamber without passing through the liquid precursor.

8. The apparatus of claim 1, wherein vapor precursor injector draws vapor from a liquid precursor.

9. The apparatus of claim 1, wherein the liquid precursor injector comprises:
a liquid metering device to control the flow of the liquid precursor; and
a vaporizer coupled to the liquid metering device to receive the liquid precursor and convert the liquid precursor into vapor.

10. The apparatus of claim 9 further comprising a vaporizer temperature controller coupled to the vaporizer.

11. The apparatus of claim 9 further comprising an atomizer coupled to the vaporizer.

12. The apparatus of claim 9 wherein the vaporizer receives a plurality of gases.

13. A method for controlling a range of deposition rate of multi-layer films deposited by CVD using liquid precursors having a vapor precursor injector and a liquid precursor injector, the method comprising:
depositing a first layer using the vapor precursor injector at a first deposition rate; and
depositing a second layer using the liquid precursor injector at a second deposition rate, wherein the second deposition rate is greater than the first deposition rate.

14. The method of claim 13, wherein the second layer is deposited after the first layer.

15. The method of claim 13, wherein the first layer is deposited after the second layer.

16. The method of claim 13, further comprising forming a multi-layer film with a plurality of alternating first and second layers.

17. The method of claim 13, wherein the liquid precursor is a liquid copper precursor.

18. The method of claim 13, wherein the liquid precursor is one of liquid copper precursor, liquid aluminum precursor, liquid ferroelectric precursor, liquid high-dielectric-constant precursor.

19. The method of claim 13, wherein the thickness of the first layer is approximately between 10 and 500 angstroms.

20. The method of claim 13, wherein the liquid precursor vapor flow of the precursor vapor injector is approximately between 10 and 1000 standard cubic centimeter per minute (sccm).

21. The method of claim 13, wherein the deposition rate of the precursor vapor injector is approximately between 10 and 500 angstroms per minute.

22. The method of claim 13, wherein the thickness of the second layer is approximately between 200 and 10000 angstroms.

23. The method of claim 13, wherein the liquid precursor flow of the liquid precursor injector is approximately between 0.1 and 5 milliliter per minute.

24. The method of claim 18 in which the deposition rate of the liquid precursor injector is approximately between 500 and 10000 angstroms per minute.

25. The method of claim 13, further comprising providing an oxidizer during the deposition of the first layer.

26. The method of claim 25 in which the oxidizer is one of oxygen, water vapor, nitrous oxide, oxygen-released chemical.

27. An apparatus controls deposition rate of multi-layer films deposited by chemical vapor deposition (CVD), comprising:
a CVD chamber;
a vapor precursor injector coupled to the CVD chamber to provide a fast deposition rate; and
a liquid precursor injector coupled to the CVD chamber to provide a slow deposition rate.

28. An apparatus controls deposition rate of multi-layer films deposited by chemical vapor deposition (CVD), comprising:
a CVD chamber;
a vapor precursor injector coupled to the CVD chamber to provide a slow deposition rate; and
a liquid precursor injector coupled to the CVD chamber to provide a fast deposition rate.
